(19) United States
(12) Patent Application Publication
(10) Pub. No.: US 2025/0212670 A1
(43) Pub. Date: Jun. 26, 2025

(54) DISPLAY DEVICE, METHOD OF MANUFACTURING THE SAME, AND ELECTRONIC DEVICE INCLUDING THE SAME

(71) Applicant: Samsung Display Co., LTD., Yongin- si (KR)

(72) Inventors: YONG SEOK KIM, Yongin-si (KR); YOUNGCHAN KIM, Yongin-si (KR); SU-YEON SIM, Yongin-si (KR)

(73) Assignee: Samsung Display Co., LTD., Yongin- si (KR)

(21) Appl. No.: 18/978,271

(22) Filed: Dec. 12, 2024

(30) Foreign Application Priority Data
Dec. 20, 2023 (KR) 10-2023-0187742

(51) Int. Cl. H10K 59/80

(52) U.S. Cl. CPC H10K 59/8792; H10K 59/871; H10K 59/873

(57) ABSTRACT

A display device includes an upper substrate controlling a viewing angle of light emitted from a lower substrate and bonded to the lower substrate, the upper substrate is divided into a viewing angle control area and an encapsulation area, the upper substrate includes an encapsulating substrate and a viewing angle control layer, the encapsulating substrate includes a base layer, a cavity defined in the viewing angle control area, and a protrusion protruding from the base layer toward the lower substrate in the encapsulation area, the viewing angle control layer is disposed in the cavity, and the viewing angle control layer includes transparent patterns and light absorption patterns arranged alternately.

### CROSS REFERENCE TO RELATED APPLICATION(S)

This application claims priority to and benefits of Korean Patent Application No. 10-2023-0187742 under 35 U.S.C. § 119, filed on Dec. 20, 2023 in the Korean Intellectual Property Office (KIPO), the content of which in its entirety is herein incorporated by reference.

### BACKGROUND

### 1. Technical Field

Implementations of the disclosure relate generally to a display device, a method of manufacturing the display device, and an electronic device including the display device.

### 2. Description of the Related Art

Generally, a display device displays an image with a wide viewing angle, but the viewing angle of the image displayed on the display device may be limited for security reasons or to improve image reflection.

### SUMMARY

Embodiments provide a display device.

Embodiments provide a method of manufacturing the display device.

Embodiments provide an electronic device including the display device.

A display device according to an embodiment may include a lower substrate, and an upper substrate disposed on the lower substrate, controlling a viewing angle of light emitted from the lower substrate, and bonded to the lower substrate. The upper substrate may include an encapsulating substrate divided into a viewing angle control area and an encapsulation area surrounding the viewing angle control area, and including a base layer, a cavity defined in the viewing angle control area, and a protrusion protruding from the base layer toward the lower substrate in the encapsulation area, and a viewing angle control layer disposed inside the cavity and including transparent patterns and light absorption patterns arranged alternately.

In an embodiment, the viewing angle control layer may be surrounded by the protrusion.

In an embodiment, a thickness of the protrusion may be greater than a thickness of the viewing angle control layer.

In an embodiment, the thickness of the protrusion may be greater than about 100 μm, and the thickness of the viewing angle control layer may be in a range of about 20 μm to about 100 μm.

In an embodiment, the upper substrate may further include a sealing member disposed under the protrusion.

In an embodiment, a thickness of the sealing member may be smaller than a thickness of the protrusion and a thickness of the viewing angle control layer.

In an embodiment, the thickness of the sealing member may be in a range of about 3 μm to about 5 μm.

In an embodiment, the upper substrate may further include a protective layer covering the viewing angle control layer.

In an embodiment, the upper substrate may further include a moisture absorption layer covering the protective layer.

In an embodiment, a thickness-to-width ratio of each of the light absorption patterns may be greater than about 5, and a period in which the light absorption patterns are arranged may be in a range of about 2 to about 4 times a width of each of the light absorption patterns.

In an embodiment, the light absorption patterns may be disposed between the transparent patterns, and a thickness of each of the light absorption patterns may be substantially equal to a thickness of each of the transparent patterns.

In an embodiment, the encapsulating substrate may include glass.

In an embodiment, the protrusion may be integral with the base layer.

In an embodiment, the lower substrate may include an emission layer, and the emission layer may include a pixel electrode, an organic emission layer, and a common electrode, and entirely overlapping the viewing angle control layer.

In an embodiment, the emission layer may be spaced apart from the viewing angle control layer.

In an embodiment, the emission layer may not contact the viewing angle control layer.

A method of manufacturing a display device according to an embodiment may include preparing a base member divided into a viewing angle control area and an encapsulation area surrounding the viewing angle control area, etching the base member to form an encapsulating substrate, the encapsulating substrate including a base layer, a cavity defined in the viewing angle control area, and a protrusion protruding from the base layer toward a lower substrate in the encapsulation area, forming transparent patterns inside the cavity, and forming light absorption patterns between the transparent patterns.

In an embodiment, the forming of the transparent patterns may include forming a transparent layer inside the cavity and patterning the transparent layer to form the transparent patterns.

In an embodiment, the method may further include before the forming of the transparent patterns, forming a sealing member on the protrusion.

In an embodiment, the method may further include forming a protective layer covering the transparent patterns and the light absorption patterns and forming a moisture absorption layer covering the protective layer.

An electronic device according to an embodiment may include a display device and a power supply configured to provide power to the display device. The display device may include a lower substrate, and an upper substrate disposed on the lower substrate, controlling a viewing angle of light emitted from the lower substrate, and bonded to the lower substrate. The upper substrate may include an encapsulating substrate divided into a viewing angle control area and an encapsulation area surrounding the viewing angle control area, and including a base layer, a cavity defined in the viewing angle control area, and a protrusion protruding from the base layer toward the lower substrate in the encapsulation area, and a viewing angle control layer disposed inside the cavity and including transparent patterns and light absorption patterns arranged alternately.

Therefore, a display device according to embodiments of the disclosure may include an upper substrate in which a viewing angle control layer is embedded. In detail, the upper substrate may include an encapsulating substrate having a cavity defined by a protrusion, and the viewing angle control layer disposed within the cavity.

As the viewing angle control layer is internalized in the upper substrate, the cost of manufacturing the display device can be reduced. For example, the cost of purchasing a conventional viewing angle adjustment layer, the cost of an adhesive for attaching a conventional viewing angle adjustment layer to a display device, the process cost for attaching a conventional viewing angle adjustment layer to a display device, etc. can be reduced.

As the viewing angle control layer is internalized in the upper substrate, durability of the display device may be improved. For example, since the viewing angle control layer is formed directly on the encapsulation substrate, deformation defects due to external impact may not occur.

The technical objectives to be achieved by the disclosure are not limited to those described herein, and other technical objectives that are not mentioned herein would be clearly understood by a person skilled in the art from the description of the disclosure.

### BRIEF DESCRIPTION OF THE DRAWINGS

The accompanying drawings, which are included to provide a further understanding of the disclosure and are incorporated in and constitute a part of this specification, illustrate embodiments of the disclosure together with the description.

FIG. 1 is a schematic perspective view illustrating a display device according to an embodiment of the disclosure.

FIG. 2 is a schematic cross-sectional view illustrating the display device of FIG. 1.

FIG. 3 is a schematic block diagram illustrating a lower substrate included in the display device of FIG. 2.

FIG. 4 is a schematic diagram of an equivalent circuit illustrating a pixel included in the lower substrate of FIG. 3.

FIG. 5 is a schematic cross-sectional view illustrating a lower substrate included in the display device of FIG. 2.

FIGS. 6 to 19 are schematic cross-sectional views illustrating a method of manufacturing the display device of FIG. 2.

FIG. 20 is a block diagram illustrating an electronic device, according to an embodiment of the disclosure.

FIG. 21 is a schematic diagram of an electronic device, according to embodiments of the disclosure.

### DETAILED DESCRIPTION OF THE EMBODIMENTS

Illustrative, non-limiting embodiments will be more clearly understood from the following detailed description in conjunction with the accompanying drawings.

When an element is referred to as being “on,” “connected to,” or “coupled to” another element, it may be directly on, connected to, or coupled to the other element or intervening elements or layers may be present. When, however, an element is referred to as being “directly on,” “directly connected to,” or “directly coupled to” another element, there are no intervening elements or layers present. To this end, the term “connected” may refer to physical, electrical, and/or fluid connection, with or without intervening elements.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

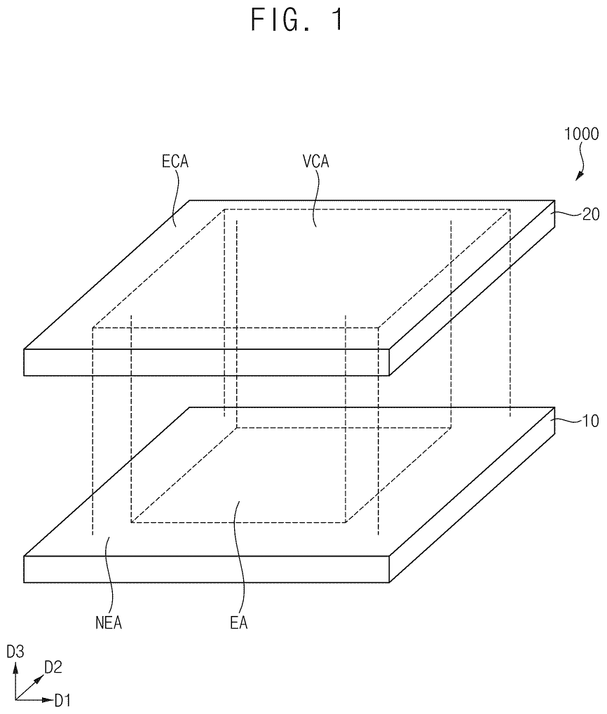

FIG. 1 is a schematic perspective view illustrating a display device according to an embodiment of the disclosure.

Referring to FIG. 1, a display device 1000 according to an embodiment of the disclosure may include a lower substrate 10 and an upper substrate 20.

The lower substrate 10 may be divided into a display area EA and a non-display area NEA surrounding the display area EA, and may emit light.

The upper substrate 20 may be disposed on the lower substrate 10 and may encapsulate or may be bonded to the lower substrate 10. In an embodiment, the upper substrate 20 may control or adjust a viewing angle of light emitted from the lower substrate 10. For example, the upper substrate 20 may be divided into a viewing angle control area VCA and an encapsulation area ECA surrounding the viewing angle control area VCA.

In an embodiment, as shown in FIG. 1, the display area EA may entirely overlap the viewing angle control area VCA. In other words, the viewing angle control area VCA may cover (or overlap) the display area EA, and the area of the viewing angle adjustment area VCA may be greater than the area of the display area EA.

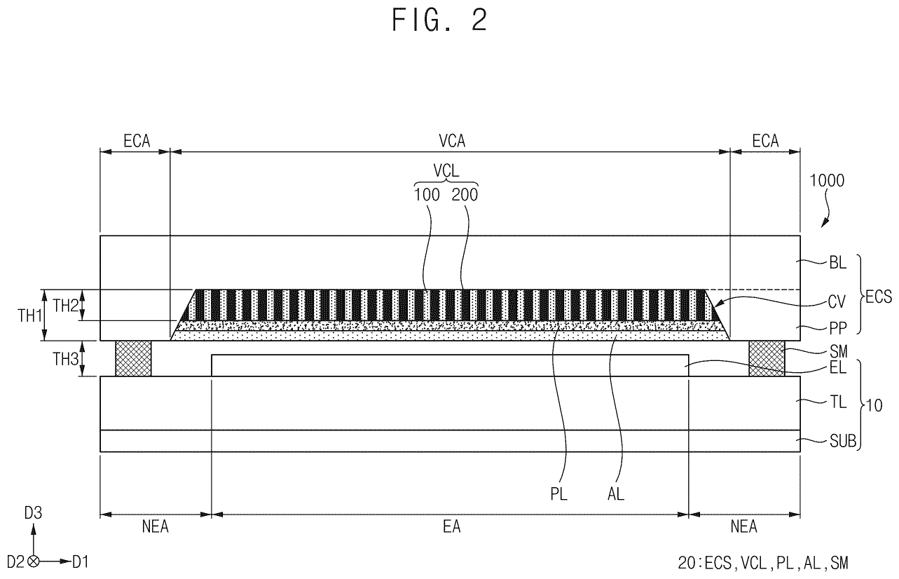

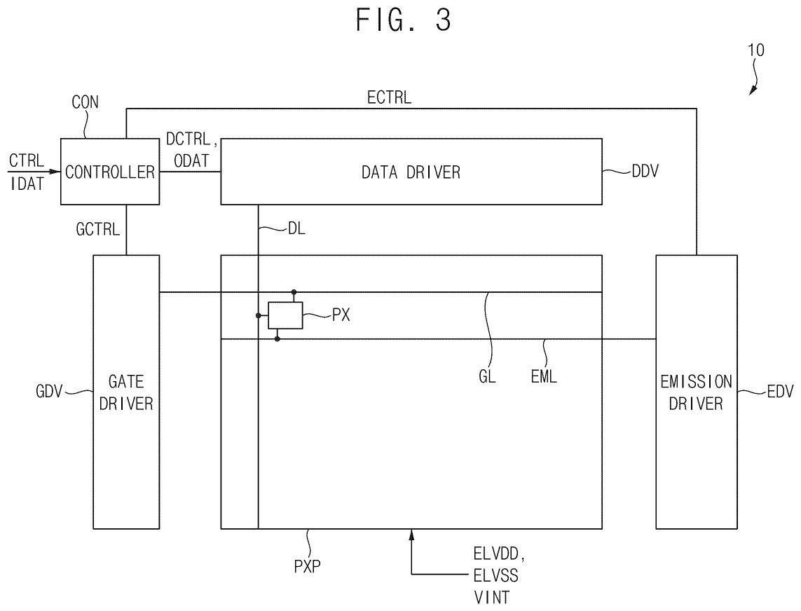

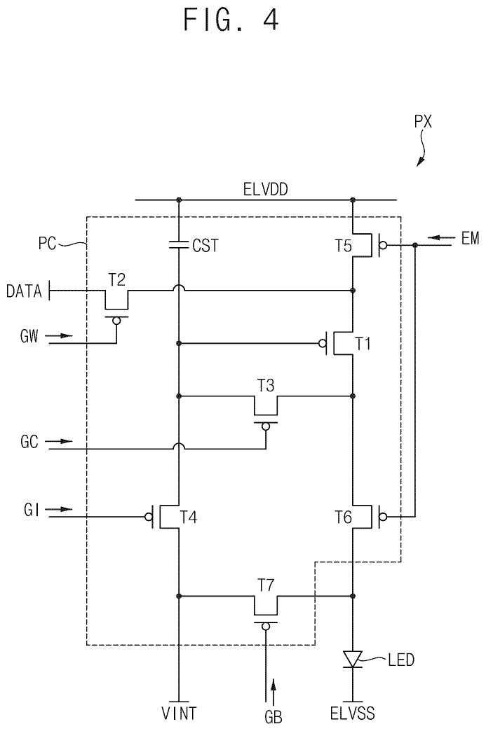

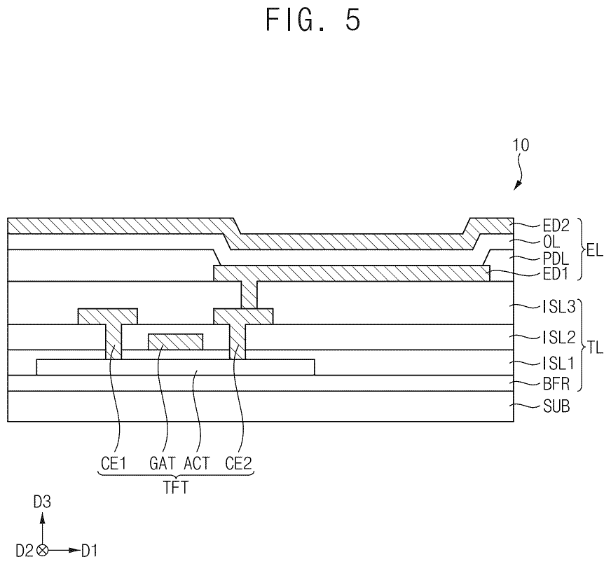

FIG. 2 is a schematic cross-sectional view illustrating the display device of FIG. 1. FIG. 3 is a schematic block diagram illustrating a lower substrate included in the display device of FIG. 2. FIG. 4 is a schematic diagram of an equivalent circuit illustrating a pixel included in the lower substrate of FIG. 3. FIG. 5 is a schematic cross-sectional view illustrating a lower substrate included in the display device of FIG. 2.

Referring to FIG. 2, the lower substrate 10 may include a base substrate SUB, a transistor layer TL, and an emission layer EL. The transistor layer TL may be disposed on the base substrate SUB and may generate driving current. The emission layer EL may be disposed on the transistor layer TL and may overlap the display area EA. The emission layer EL may generate light based on the driving current.

Referring to FIG. 3, the lower substrate 10 may include a pixel part PXP, a gate driver GDV, a data driver DDV, an emission driver EDV, and a controller CON.

The pixel part PXP may include at least one pixel PX and may be provided with a voltage (e.g., a power voltage and/or a data voltage) for driving the pixel PX. The pixel part PXP may include a data line DL connected to the pixel PX, a gate line GL connected to the pixel PX, and an emission control line EML connected to the pixel PX.

The gate driver GDV may generate gate signals GW, GC, GI, and GB based on a gate control signal GCTRL. For example, the gate signals GW, GC, GI, and GB may include a gate-on voltage that turns on the transistor and a gate-off voltage that turns off the transistor. The gate control signal GCTRL may include a vertical start signal, a clock signal, etc.

The data driver DDV may generate a data voltage DATA based on an output image data ODAT and a data control signal DCTRL. For example, the data driver DDV may generate the data voltage DATA corresponding to the output image data ODAT and may output the data voltage DATA in response to the data control signal DCTRL. The data control signal DCTRL may include an output data enable signal, a horizontal start signal, and/or a load signal.

The emission driver EDV may generate the emission control signal EM based on an emission drive signal ECTRL. For example, the emission driving signal ECTRL may include a vertical start signal, a clock signal, etc., and the emission control signal EM may include a gate-on voltage that turns on the transistor and a gate-off voltage that turns off the transistor.

The controller CON (e.g., a timing controller (T-CON)) may receive an input image data IDAT and a control signal CTRL from an external host processor (e.g., GPU). For example, the input image data IDAT may be RGB data including red image data, green image data, and blue image data. The control signal CTRL may include a vertical synchronization signal, a horizontal synchronization signal, an input data enable signal, and/or a master clock signal. The controller CON may generate the gate control signal GCTRL, the emission driving signal ECTRL, the data control signal DCTRL, and the output image data ODAT, based on the input image data IDAT and the control signal CTRL.

Referring to FIG. 4, the pixel PX may include a pixel circuit PC and a light emitting diode LED. The pixel circuit PC may provide the driving current to the light emitting diode LED, and the light emitting diode LED may generate light based on the driving current.

Examples of the light emitting diode LED may include an organic light emitting diode, an inorganic light emitting diode, a nano light emitting diode, etc.

The pixel circuit PC may include a first transistor T1, a second transistor T2, a third transistor T3, a fourth transistor T4, a fifth transistor T5, a sixth transistor T6, a seventh transistor T7, and a storage capacitor CST.

The light emitting diode LED may include a first terminal (e.g., an anode terminal) and a second terminal (e.g., a cathode terminal). The first terminal of the light emitting diode LED may be connected to the sixth transistor T6 and the seventh transistor T7, and the second terminal may be provided with a second power voltage ELVSS. The light emitting diode LED may generate light with a brightness corresponding to the driving current.

The storage capacitor CST may include a first terminal and a second terminal. The first terminal of the storage capacitor CST may be connected to the first transistor T1, and the second terminal of the storage capacitor CST may receive a first power voltage ELVDD. The storage capacitor CST may maintain the voltage level of the gate terminal of the first transistor T1 during the deactivation period of a first gate signal GW.

The first transistor T1 may include a gate terminal, a first terminal, and a second terminal. The gate terminal of the first transistor T1 may be connected to the first terminal of the storage capacitor CST. The first terminal of the first transistor T1 may be connected to the second transistor T2 and may receive the data voltage DATA. The second terminal of the first transistor T1 may be connected to the sixth transistor T6. The first transistor T1 may generate the driving current based on the voltage difference between the gate terminal and the first terminal. For example, the first transistor T1 may be referred to as a driving transistor.

The second transistor T2 may include a gate terminal, a first terminal, and a second terminal. The gate terminal of the second transistor T2 may receive the first gate signal GW through the gate line GL.

The second transistor T2 may be turned on or off in response to the first gate signal GW. For example, in case that the second transistor T2 is a PMOS transistor, the second transistor T2 may be turned off in case that the first gate signal GW has a positive voltage level, and the first gate signal GW may be turned on in case that the first gate signal GW has a negative voltage level. The first terminal of the second transistor T2 may receive the data voltage DATA through the data line DL. The second terminal of the second transistor T2 may provide the data voltage DATA to the first terminal of the first transistor T1 during the period in which the second transistor T2 is turned on. For example, the second transistor T2 may be referred to as a switching transistor.

The third transistor T3 may include a gate terminal, a first terminal, and a second terminal. The gate terminal of the third transistor T3 may receive a second gate signal GC. The first terminal of the third transistor T3 may be connected to the second terminal of the first transistor T1. The second terminal of the third transistor T3 may be connected to the gate terminal of the first transistor T1.

The third transistor T3 may be turned on or off in response to the second gate signal GC. For example, in case that the third transistor T3 is a PMOS transistor, the third transistor T3 may be turned off in case that the second gate signal GC has a positive voltage level, and the second gate signal GC may be turned on in case that the second gate signal GC has a negative voltage level.

During a period in which the third transistor T3 is turned on in response to the second gate signal GC, the third transistor T3 may diode-connect the first transistor T1. Accordingly, the third transistor T3 may compensate for the threshold voltage of the first transistor T1. For example, the third transistor T3 may be referred to as a compensation transistor.

The fourth transistor T4 may include a gate terminal, a first terminal, and a second terminal. The gate terminal of the fourth transistor T4 may receive a third gate signal GI. The first terminal of the fourth transistor T4 may be connected to the gate terminal of the first transistor T1. The second terminal of the fourth transistor T4 may receive an initialization voltage VINT.

The fourth transistor T4 may be turned on or off in response to the third gate signal GI. For example, in case that the fourth transistor T4 is a PMOS transistor, the fourth transistor T4 may be turned off in case that the third gate signal GI has a positive voltage level, and the fourth transistor T4 may be turn on when the third gate signal GI has a negative voltage level.

During a period in which the fourth transistor T4 is turned on by the third gate signal GI, the initialization voltage VINT may be provided to the gate terminal of the first transistor T1. Accordingly, the fourth transistor T4 can initialize the gate terminal of the first transistor T1 to the initialization voltage VINT. For example, the fourth transistor T4 may be referred to as a gate initialization transistor.

The fifth transistor T5 may include a gate terminal, a first terminal, and a second terminal. The gate terminal of the fifth transistor T5 may receive the emission control signal EM. The first terminal of the fifth transistor T5 may receive the first power voltage ELVDD. The second terminal of the fifth transistor T5 may be connected to the first transistor T1. In case that the fifth transistor T5 is turned on in response to the emission control signal EM, the fifth transistor T5 may provide the first power voltage ELVDD to the first transistor T1.

The sixth transistor T6 may include a gate terminal, a first terminal, and a second terminal. The gate terminal of the sixth transistor T6 may receive the emission control signal EM. The first terminal of the sixth transistor T6 may be connected to the first transistor T1. The second terminal of the sixth transistor T6 may be connected to the light emitting diode LED. In case that the sixth transistor T6 is turned on in response to the emission control signal EM, the sixth transistor T6 may provide the driving current to the light emitting diode LED.

The seventh transistor T7 may include a gate terminal, a first terminal, and a second terminal. The gate terminal of the seventh transistor T7 may receive a fourth gate signal GB. The first terminal of the seventh transistor T7 may be connected to the light emitting diode LED. The second terminal of the seventh transistor T7 may receive the initialization voltage VINT.

In case that the seventh transistor T7 is turned on in response to the fourth gate signal GB, the seventh transistor T7 may provide the initialization voltage VINT to the light emitting diode LED. Accordingly, the seventh transistor T7 can initialize the first terminal of the light emitting diode LED to the initialization voltage VINT. For example, the seventh transistor T7 may be referred to as an anode initialization transistor.

However, the structure of the pixel circuit PC is not limited to the above-described structure. For example, the number of transistors, number of capacitors, and types of transistors (PMOS, NMOS, etc.) included in the pixel circuit PC can be appropriately set as needed.

Referring to FIG. 5, the transistor layer TL may include a buffer layer BFR, an active pattern ACT, a first insulating layer ISL1, a gate electrode GAT, a second insulating layer ISL2, a first connection electrode CE1, a second connection electrode CE2, and/or a third insulating layer ISL3. The first connection electrode CE1, gate electrode GAT, active pattern ACT, and the second connection electrode CE2 may form a transistor TFT. The emission layer EL may include a pixel electrode ED1, a pixel defining layer PDL, an organic emission layer OL, and a common electrode ED2.

The base substrate SUB may be formed of glass, quartz, plastic, etc. In an embodiment, in case that the display device 1000 is a rigid display device, the base substrate SUB may be made of (or include) glass. In another embodiment, in case that the display device 1000 is a flexible display device, the base substrate SUB may be made of plastic. Examples of plastics that can be used in the base substrate SUB may include polyimide PI, polyethylene terephthalate PET, etc. These can be used alone or in combination with each other.

The buffer layer BFR may be disposed on the substrate SUB. In an embodiment, the buffer layer BFR may be formed of (or include) an insulating material. Examples of materials that can be used in the buffer layer BFR may include silicon oxide, silicon nitride, and silicon oxynitride. These can be used alone or in combination with each other.

The active pattern ACT may be disposed on the buffer layer BFR. In an embodiment, the active pattern ACT may be formed of an oxide semiconductor, a silicon semiconductor, or the like.

The first insulating layer ISL1 may be disposed on the buffer layer BFR and may cover (or overlap) the active pattern ACT. In an embodiment, the first insulating layer ISL1 may be formed of an insulating material. Examples of materials that can be used as the first insulating layer ISL1 may include silicon oxide, silicon nitride, and silicon oxynitride. These can be used alone or in combination with each other.

The gate electrode GAT may be disposed on the first insulating layer ISL1 and may overlap the active pattern ACT. In an embodiment, the gate electrode GAT may be formed, e.g., of metal, alloy, conductive metal oxide, transparent conductive material, etc. Examples of materials that can be used as the gate electrode GAT may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum. (Pt), scandium (Sc), indium tin oxide (ITO), indium zinc oxide (IZO), etc. These can be used alone or in combination with each other.

The second insulating layer ISL2 may be disposed on the first insulating layer ISL1 and may cover the gate electrode GAT. In an embodiment, the second insulating layer ISL2 may be formed of an insulating material. Examples of materials that can be used as the second insulating layer ISL2 may include silicon oxide, silicon nitride, and silicon oxynitride. These can be used alone or in combination with each other.

The first connection electrode CE1 and the second connection electrode CE2 may be disposed on the second insulating layer ISL2 and may contact the active pattern ACT. In an embodiment, the first connection electrode CE1 and the second connection electrode CE2 may be formed of, e.g., metal, alloy, conductive metal oxide, transparent conductive material, etc. Examples of materials that can be used as the first connection electrode CE1 and the second connection electrode CE2 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), and indium zinc oxide (IZO), etc. These can be used alone or in combination with each other.

The third insulating layer ISL3 may be disposed on the second insulating layer ISL2 and may cover the first connection electrode CE1 and the second connection electrode CE2. In an embodiment, the third insulating layer ISL3 may be formed of an insulating material. Examples of materials that can be used as the third insulating layer ISL3 may include photoresist, polyacrylic resin, polyimide resin, and acrylic resin. These can be used alone or in combination with each other.

The pixel electrode ED1 may be disposed on the third insulating layer ISL3 and may contact the second connection electrode CE2. The pixel defining layer PDL may be disposed on the third insulating layer ISL3 and may include an opening exposing the pixel electrode ED1. The organic emission layer OL may be disposed on the pixel electrode ED1. The common electrode ED2 may be disposed on the organic emission layer OL.

In an embodiment, as the upper substrate 20 encapsulates the lower substrate 10, the lower substrate 10 may not include an additional thin film encapsulation (TFE) layer.

Referring again to FIG. 2, the upper substrate 20 may include an encapsulating substrate ECS, a viewing angle control layer VCL, a protective layer PL, a moisture absorption layer AL, and/or a sealing member SM.

In an embodiment, the encapsulating substrate ECS may include a base layer BL, a cavity CV, and a protrusion PP.

In an embodiment, the base layer BL may be parallel to a plane consisting of a first direction D1 and a second direction D2 and may have a thickness in a third direction D3. In an embodiment, the base layer BL may be made of, e.g., glass and may protect underlying components.

In an embodiment, the cavity CV may be defined in the viewing angle control area VCA and may face the lower substrate 10. The cavity CV may be defined as an empty space formed in the encapsulating substrate ECS, and a boundary of the cavity CV may be set by the protrusion PP.

In an embodiment, the protrusion PP may protrude from the base layer BL toward the lower substrate 10 in the encapsulation area ECA, and the protrusion PP may define a boundary of the cavity CV. The protrusion PP may be integral with the base layer BL and may be made of, e.g., glass.

In an embodiment, the viewing angle control layer VCL may be internalized in the encapsulating substrate ECS and may be formed directly on the encapsulating substrate ECS. For example, the viewing angle control layer VCL may be disposed within the cavity CV and may be surrounded by the protrusion PP.

In an embodiment, the emission layer EL may entirely overlap the viewing angle control layer VCL. In other words, the planar area of the viewing angle control layer VCL may be larger than the planar area of the emission layer EL.

In an embodiment, the emission layer EL may be spaced apart from the viewing angle control layer VCL. For example, the emission layer EL may not contact the viewing angle control layer VCL.

In an embodiment, the viewing angle control layer VCL may include transparent patterns 100 and light absorption patterns 200. The transparent patterns 100 and the light absorption patterns 200 may be arranged side by side, alternating with each other along the first direction D1 and the second direction D2. In other words, the transparent patterns 100 may function as a mold that fixes the light absorption patterns 200.

For example, each of the light absorption patterns 200 may have a thickness in the third direction D3 and a width in the first direction D1. In this case, the thickness-to-width ratio of each of the light absorption patterns 200 may be greater than about 5.

A period in which the light absorption patterns 200 are arranged in the first direction D1 may be in a range of about 2 to about 4 times the width of each of the light absorption patterns 200.

The thickness of each of the light absorption patterns 200 may be substantially equal to the thickness of each of the transparent patterns 100.

In an embodiment, the transparent patterns 100 may include a material with relatively high light transmittance. For example, the transparent patterns 100 may be made of photoresist, polyacryl-based resin, polyimide-based resin, polyamide-based resin, siloxane-based resin, acryl-based resin, epoxy-based resin, etc. These can be used alone or in combination with each other. The transparent patterns 100 may transmit light emitted from the emission layer EL.

In an embodiment, the light absorption patterns 200 may include a material with relatively low light transmittance. For example, the light absorption patterns 200 may include black dye, black pigment, carbon black, chrome, etc. These can be used alone or in combination with each other. The light absorption patterns 200 may absorb or block light emitted from the emission layer EL.

In an embodiment, the protective layer PL may be disposed under the viewing angle control layer VCL and may cover the viewing angle control layer VCL. The protective layer PL may maintain the shape of the viewing angle control layer VCL and may protect the viewing angle control layer VCL. In an embodiment, the protective layer PL may include a transparent inorganic material or a transparent metal oxide. Examples of inorganic materials that can be used as the protective layer PL may include silicon oxide, silicon nitride, and silicon oxynitride. Examples of metal oxides that can be used as the protective layer PL may include indium tin oxide (ITO), indium zinc oxide (IZO), and indium gallium tin oxide (IGZO).

In an embodiment, the moisture absorption layer AL may be disposed under the protective layer PL and may cover the protective layer PL. The moisture absorption layer AL may include a hygroscopic material and can absorb moisture and/or oxygen.

In an embodiment, the sealing member SM may overlap the encapsulation area ECA and the non-display area NEA, and may be disposed between the protrusion PP and the transistor layer TL. The sealing member SM may be positioned between the encapsulating substrate ECS and the lower substrate 10 to seal the internal space. For example, frit may be used as the sealing member SM. Therefore, after applying a frit to the lower part of the protrusion PP and covering the encapsulating substrate ECS, in case that a laser or heat is applied to the frit, the frit may be hardened and may be seal the encapsulating substrate ECS and the lower substrate 10. In this case, the internal space may be filled with fillers, moisture absorbents, etc.

In an embodiment, the protrusion PP may have a first thickness TH1 in the third direction D3, the viewing angle control layer VCL may have a second thickness TH2 in the third direction D3, and the sealing member SM may have a third thickness TH3 in the third direction D3.

In an embodiment, the first thickness TH1 of the protrusion PP may be greater than the second thickness TH2 of the viewing angle control layer VCL. For example, the first thickness TH1 may be greater than about 100 μm, and the second thickness TH2 may be about 20 μm to about 100 μm. Accordingly, the viewing angle control layer VCL may be protected by the protrusion PP and may be internalized in the encapsulating substrate ECS.

In an embodiment, the third thickness TH3 of the sealing member SM may be smaller than the first thickness TH1 of the protrusion PP and the second thickness TH2 of the viewing angle control layer VCL. For example, the third thickness TH3 may be in a range of about 3 μm to about 5 μm.

The display device 1000 according to an embodiment of the disclosure may include the upper substrate 20 in which the viewing angle control layer VCL is embedded. In detail, the upper substrate 20 may include the encapsulating substrate ECS with the cavity CV defined by the protrusion PP and the viewing angle control layer VCL disposed within the cavity CV.

As the viewing angle control layer VCL is internalized in the upper substrate 20, the cost of manufacturing the display device 1000 can be reduced. For example, the cost of purchasing a conventional viewing angle control layer, the cost of an adhesive for attaching a conventional viewing angle control layer to a display device, the process cost for attaching a conventional viewing angle control layer to a display device, etc. can be reduced.

As the viewing angle control layer VCL is internalized in the upper substrate 20, durability of the display device 1000 may be improved. For example, since the viewing angle control layer VCL is formed directly on the encapsulating substrate ECS, deformation defects due to external impact may not occur.

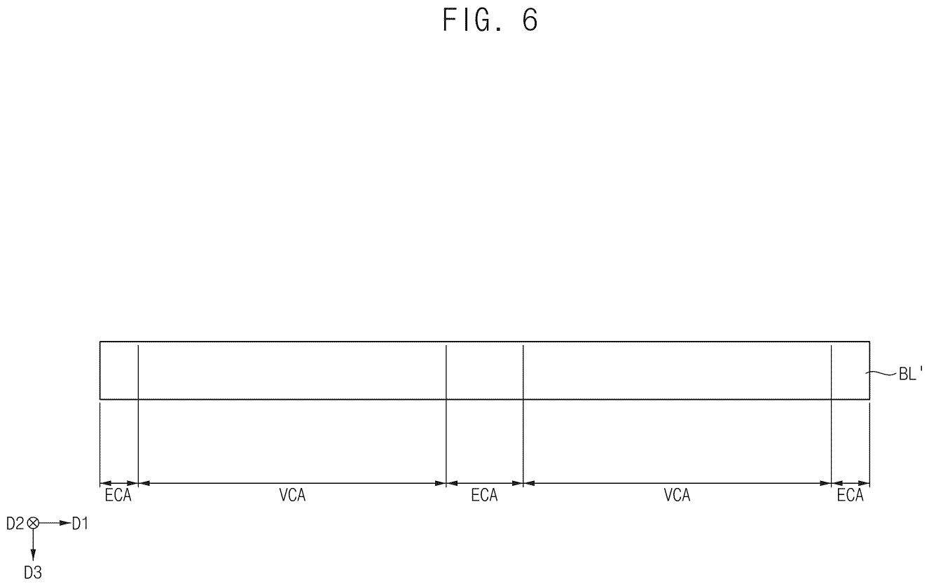

FIGS. 6 to 19 are schematic cross-sectional views illustrating a method of manufacturing the display device of FIG. 2.

Referring to FIG. 6, a base member BL′ divided into a viewing angle control area VCA and an encapsulation area ECA surrounding the viewing angle control area VCA may be prepared. For example, the base member BL′ may be made of (or include) glass.

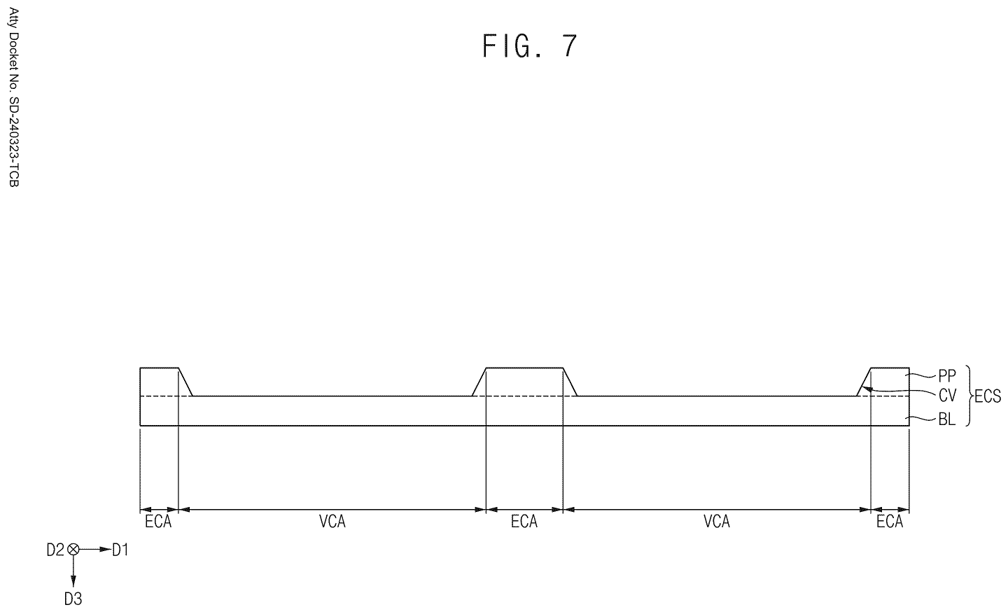

Referring to FIG. 7, the encapsulating substrate ECS may be formed by etching the base member BL′. In detail, the base member BL′ corresponding to the viewing angle control area VCA may be etched. Accordingly, the cavity CV defined in the viewing angle control area VCA and the protrusion PP protruding from the encapsulation area ECA may be formed.

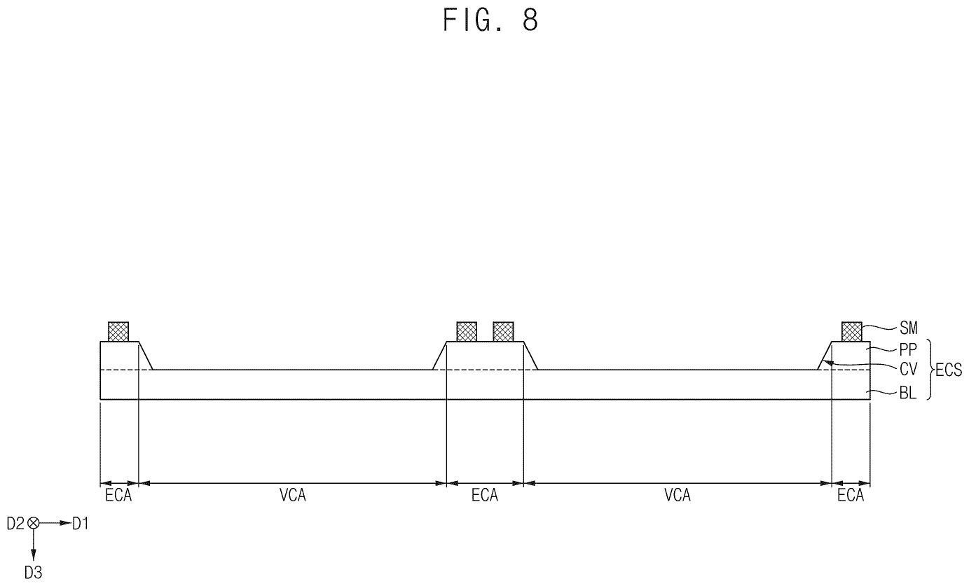

Referring to FIG. 8, the sealing member SM may be formed on the protrusion PP. In an embodiment, the sealing member SM may be plasticized. As the plasticizing process is performed before the viewing angle control layer VCL is formed, the reliability of the viewing angle control layer VCL may be improved.

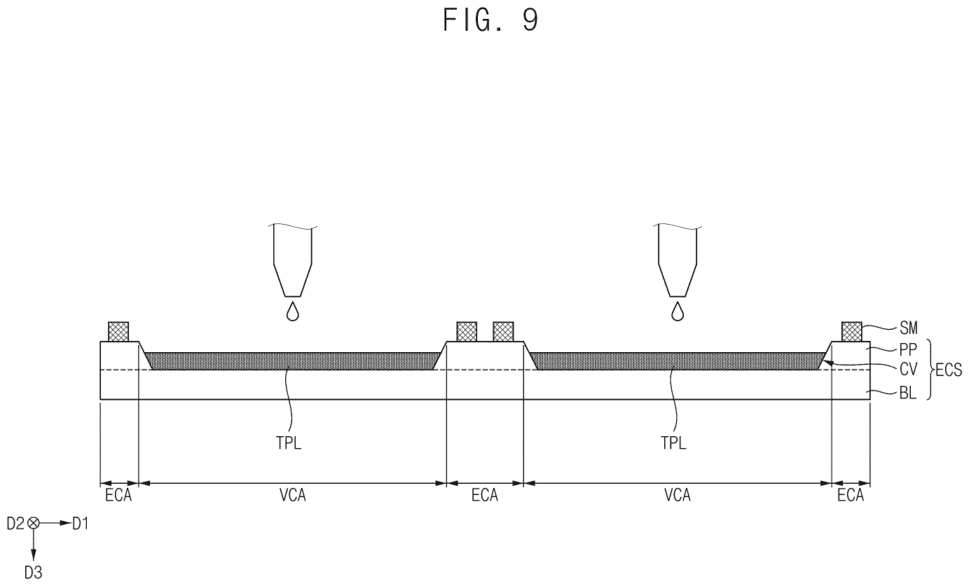

Referring to FIG. 9, a transparent layer TPL may be formed within the cavity CV. In an embodiment, the transparent layer TPL may be printed through an inkjet process. The transparent layer TPL may include a material with relatively high light transmittance.

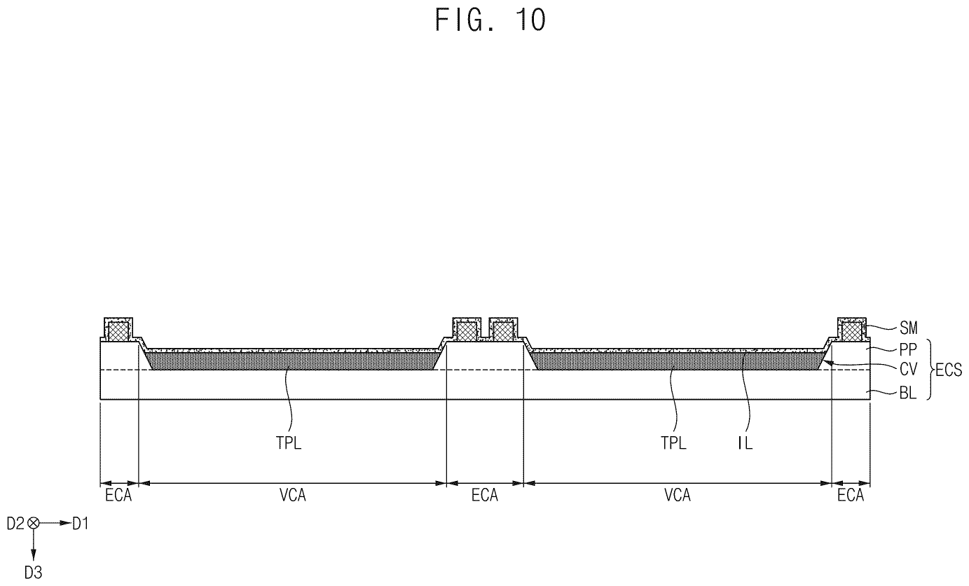

Referring to FIG. 10, an inorganic layer IL may be formed on the transparent layer TPL. The inorganic layer IL may include an inorganic material or a metal oxide, and may be formed using, e.g., chemical vapor deposition (CVD) process, sputtering process, etc.

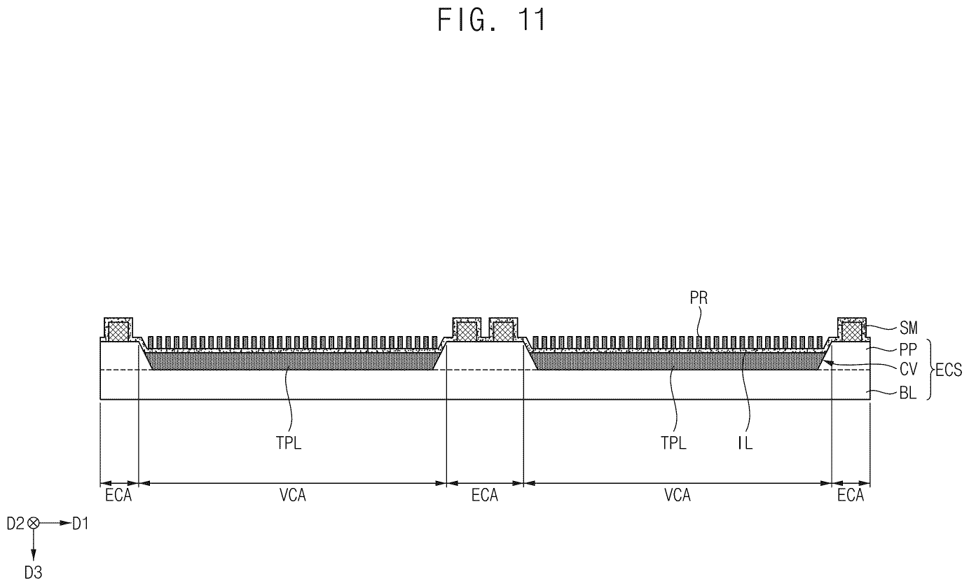

Referring to FIG. 11, a photoresist pattern PR may be formed on the inorganic layer IL. The photoresist pattern PR may include photoresist and may be patterned to correspond to grooves formed in the transparent patterns 100.

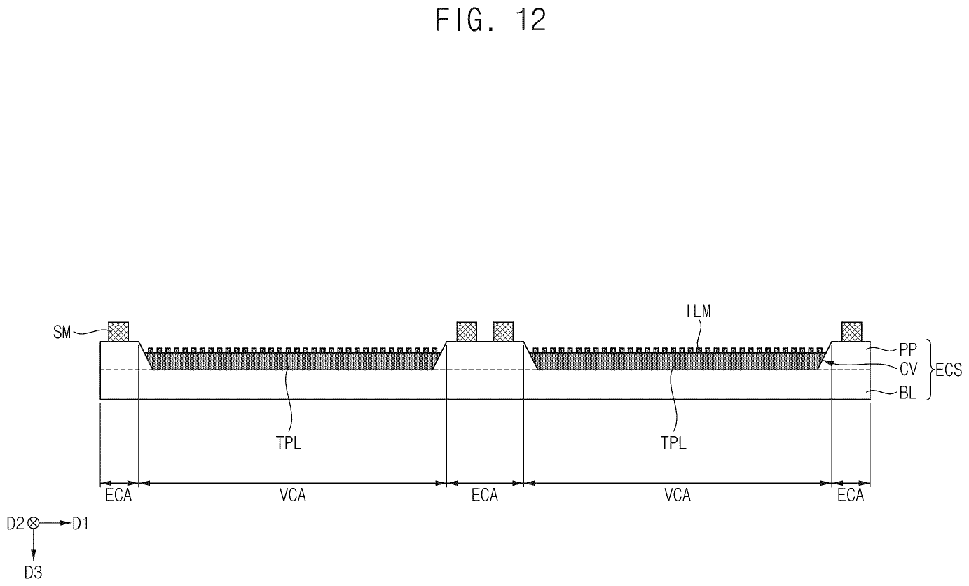

Referring to FIG. 12, a mask ILM may be formed. For example, the inorganic layer IL may be etched corresponding to the photoresist pattern PR, and the remaining inorganic layer IL may function as the mask ILM.

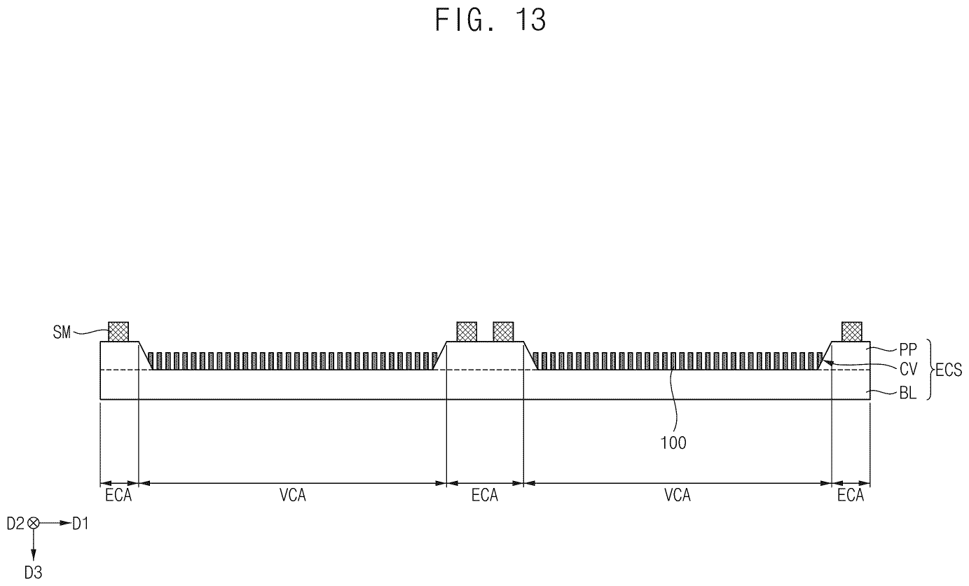

Referring to FIG. 13, the transparent patterns 100 may be formed. For example, the transparent layer TPL may be patterned to correspond to the pattern of the mask ILM, and the remaining transparent layer TPL may function as the transparent patterns 100.

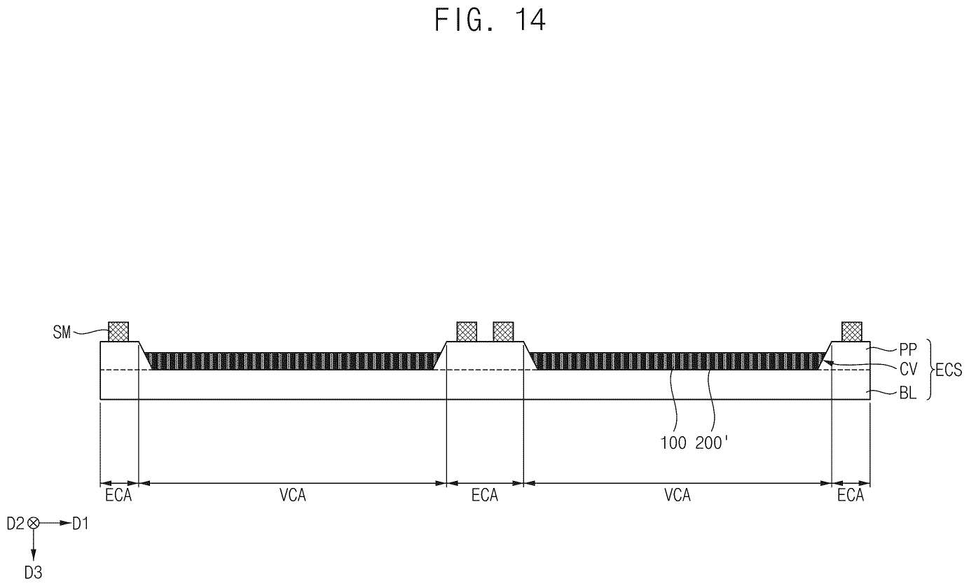

Referring to FIG. 14, preliminary light absorption patterns 200′ may be formed between the transparent patterns 100. The preliminary light absorption patterns 200′ may be entirely applied or printed on the transparent patterns 100 and may fill grooves defined between the transparent patterns 100.

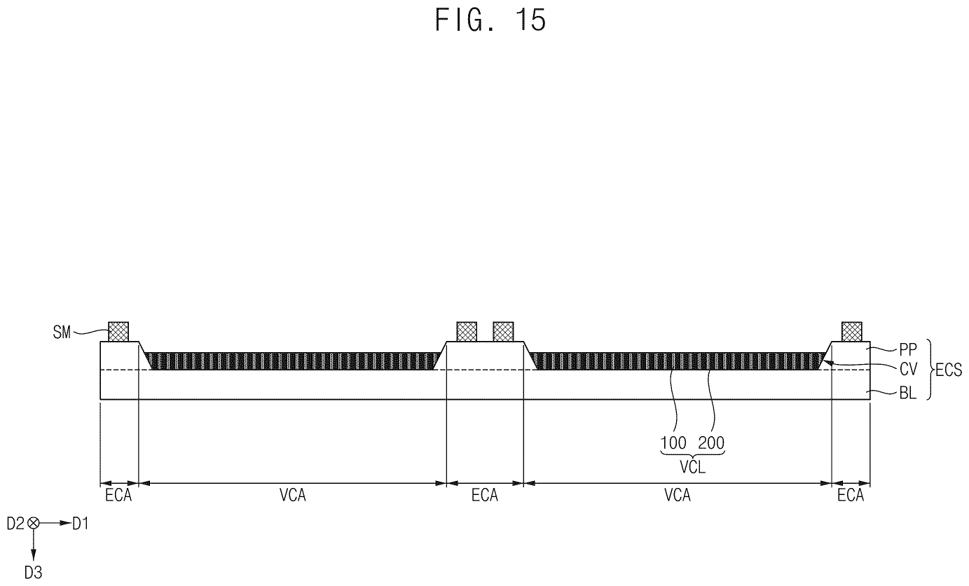

Referring to FIG. 15, the light absorption patterns 200 may be formed by curing the preliminary light absorption patterns 200′. For example, the preliminary light absorption patterns 200′ may be cured at about 230° C. in a nitrogen atmosphere or a vacuum atmosphere.

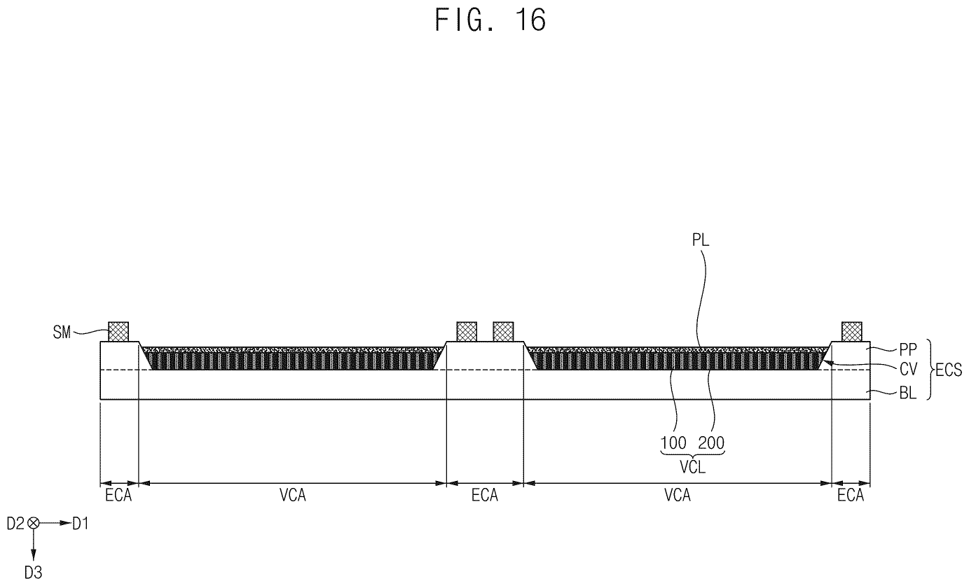

Referring to FIG. 16, the protective layer PL may be formed on the transparent patterns 100 and the light absorption patterns 200. For example, an inorganic material or metal oxide may be deposited using an open mask or the like.

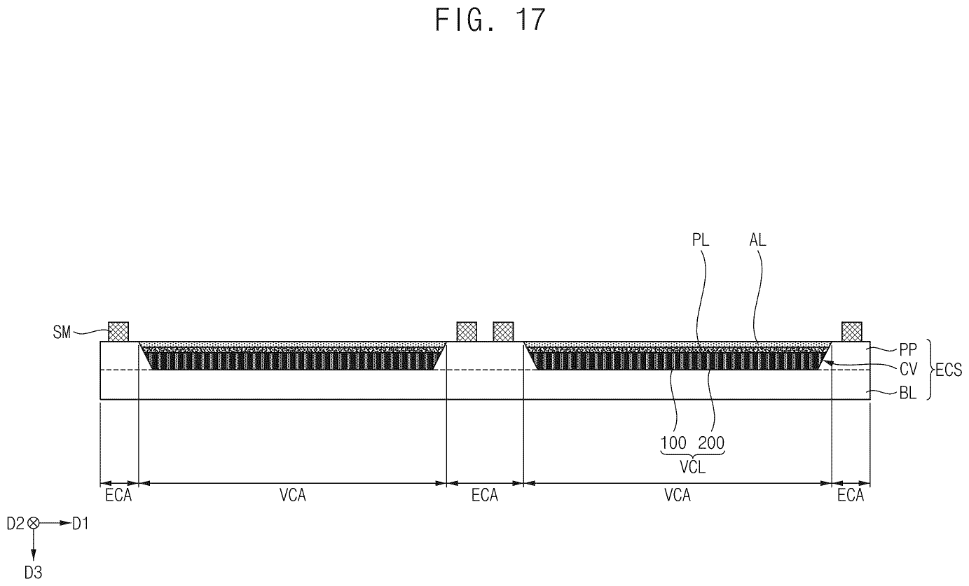

Referring to FIG. 17, a moisture absorption layer AL may be formed on the protective layer PL. In an embodiment, the protective layer PL and the moisture absorption layer AL may be formed in a nitrogen atmosphere or a vacuum atmosphere. In another embodiment, the protective layer PL and the moisture absorption layer AL may be omitted.

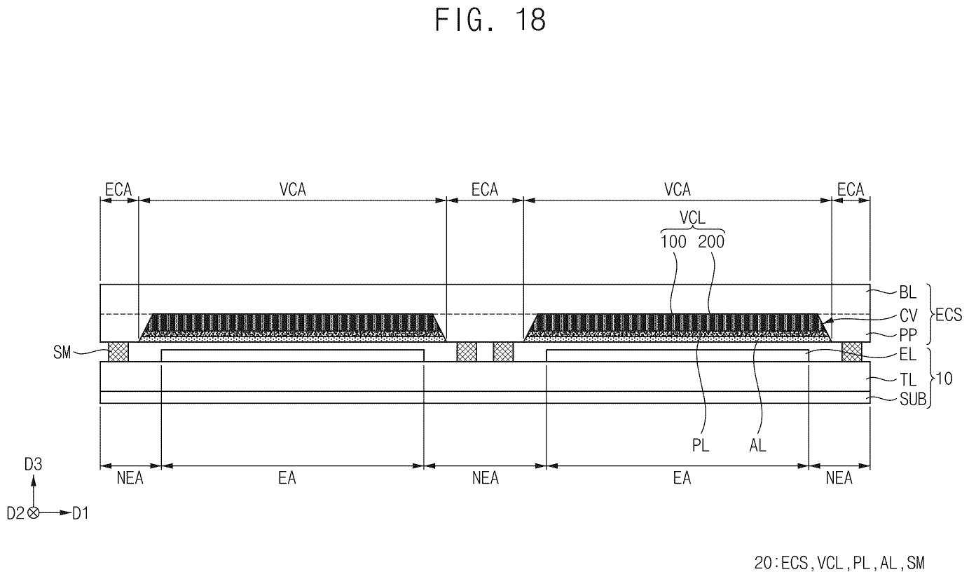

Referring to FIG. 18, the formed upper substrate 20 may be bonded to the prepared lower substrate 10.

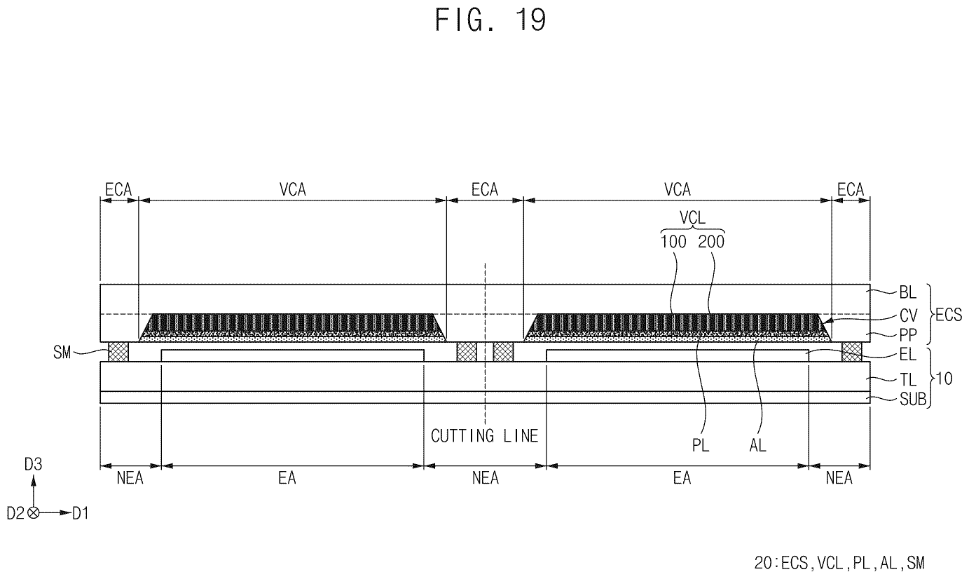

Referring to FIG. 19, the display device 1000 may be manufactured by cutting each cell along a cutting line.

The display device 1000 according to embodiments of the present disclosure may be applied to various electronic devices. An electronic device according to an embodiment of the present disclosure may include the display device 1000 described above, and may further include a module or device having additional functions in addition to the display device 1000.

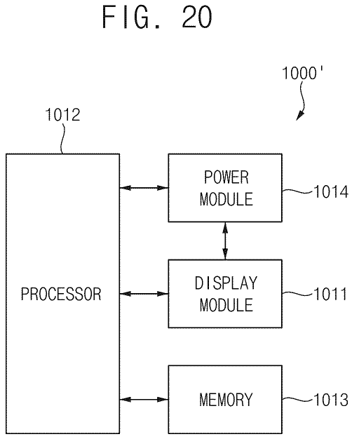

FIG. 20 is a block diagram illustrating an electronic device according to an embodiment of the disclosure.

Referring to FIG. 20, an electronic device 1000′ may include a display module 1010, a processor 1020, a memory 1030, and a power module 1040.

The processor 1020 may include at least one of a central processing unit (CPU), an application processor (AP), a graphic processing unit (GPU), a communication processor (CP), an image signal processor (ISP), and a controller.

The memory 1030 may store data information necessary for an operation of the processor 1020 or the display module 1010. When the processor 1020 executes an application stored in the memory 1030, an image data signal and/or an input control signal may be transmitted to the display module 1010, and the display module 1010 may process the received signal and output image information through a display screen.

The power module 1040 may include a power supply module such as a power adapter, a battery device, or the like and a power conversion module that converts power supplied by the power supply module to generate power necessary for an operation of the electronic device 1000′.

At least one of the components of the electronic device 1000′ described above may be included in the display device according to embodiments described above. In addition, some of individual modules functionally included in one module may be included in the display device, and others may be provided separately from the display device. For example, the display device may include the display module 1010, and the processor 1020, the memory 1030, and the power module 1040 may be provided in form of other devices in the electronic device 1000′ other than the display device.

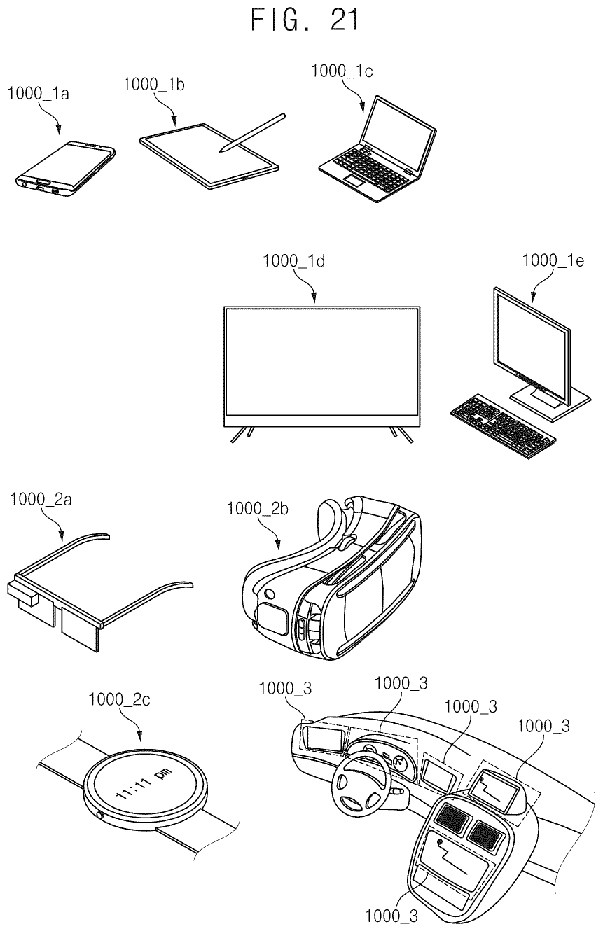

FIG. 21 is a schematic diagram of an electronic device according to embodiments of the present disclosure.

Referring to FIG. 21, various electronic devices to which the display device according to embodiments of the present disclosure are applied may include not only an image display electronic device, but also a wearable electronic device including a display module, a vehicle electronic device 1000_3 including a display module, or the like. The image display electronic device may be a smartphone 1000_1a, a tablet PC 1000_1b, a laptop 1000_1c, a TV 1000_1d, a desk monitor 1000_le, or the like. The wearable electronic device may be smart glasses 1000_2a, a head mounted display 1000_2b, a smart watch 1000_2c, or the like. The vehicle electronic device 1000_3 may be a center information display (CID) disposed on a dashboard and center fascia of a vehicle, a room mirror display, or the like.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a lower substrate; and
an upper substrate disposed on the lower substrate, controlling a viewing angle of light emitted from the lower substrate, and bonded to the lower substrate,
wherein the upper substrate includes:
an encapsulating substrate divided into a viewing angle control area and an encapsulation area surrounding the viewing angle control area, and including:
a base layer;
a cavity defined in the viewing angle control area; and
a protrusion protruding from the base layer toward the lower substrate in the encapsulation area; and
a viewing angle control layer disposed inside the cavity and including transparent patterns and light absorption patterns arranged alternately.

2. The display device of claim 1, wherein the viewing angle control layer is surrounded by the protrusion.

3. The display device of claim 1, wherein a thickness of the protrusion is greater than a thickness of the viewing angle control layer.

4. The display device of claim 3, wherein
the thickness of the protrusion is greater than about 100 μm, and
the thickness of the viewing angle control layer is in a range of about 20 μm to about 100 μm.

5. The display device of claim 1, wherein the upper substrate further includes a sealing member disposed under the protrusion.

6. The display device of claim 5, wherein a thickness of the sealing member is smaller than a thickness of the protrusion and a thickness of the viewing angle control layer.

7. The display device of claim 6, wherein the thickness of the sealing member is in a range of about 3 μm to about 5 μm.

8. The display device of claim 1, wherein the upper substrate further includes a protective layer covering the viewing angle control layer.

9. The display device of claim 8, wherein the upper substrate further includes a moisture absorption layer covering the protective layer.

10. The display device of claim 1, wherein
a thickness-to-width ratio of each of the light absorption patterns is greater than about 5, and
a period in which the light absorption patterns are arranged is in a range of about 2 to about 4 times a width of each of the light absorption patterns.

11. The display device of claim 1, wherein
the light absorption patterns are disposed between the transparent patterns, and
a thickness of each of the light absorption patterns is substantially equal to a thickness of each of the transparent patterns.

12. The display device of claim 1, wherein the encapsulating substrate includes glass.

13. The display device of claim 12, wherein the protrusion is integral with the base layer.

14. The display device of claim 1, wherein
the lower substrate includes an emission layer, and
the emission layer includes a pixel electrode, an organic emission layer, and a common electrode, and entirely overlapping the viewing angle control layer.

15. The display device of claim 14, wherein the emission layer is spaced apart from the viewing angle control layer.

16. The display device of claim 14, wherein the emission layer does not contact the viewing angle control layer.

17. A method of manufacturing a display device, the method comprising:
preparing a base member divided into a viewing angle control area and an encapsulation area surrounding the viewing angle control area;
etching the base member to form an encapsulating substrate, the encapsulating substrate including a base layer, a cavity defined in the viewing angle control area, and a protrusion protruding from the base layer toward a lower substrate in the encapsulation area;
forming transparent patterns inside the cavity; and
forming light absorption patterns between the transparent patterns.

18. The method of claim 17, wherein the forming of the transparent patterns includes:
forming a transparent layer inside the cavity; and
patterning the transparent layer to form the transparent patterns.

19. The method of claim 17, further comprising:
before the forming of the transparent patterns, forming a sealing member on the protrusion.

20. The method of claim 17, further comprising:
forming a protective layer covering the transparent patterns and the light absorption patterns; and
forming a moisture absorption layer covering the protective layer.

21. An electronic device comprising:
a display device; and
a power supply configured to provide power to the display device,
wherein the display device comprises:
a lower substrate; and
an upper substrate disposed on the lower substrate, controlling a viewing angle of light emitted from the lower substrate, and bonded to the lower substrate,
wherein the upper substrate includes:
an encapsulating substrate divided into a viewing angle control area and an encapsulation area surrounding the viewing angle control area, and including:
a base layer;
a cavity defined in the viewing angle control area; and
a protrusion protruding from the base layer toward the lower substrate in the encapsulation area; and
a viewing angle control layer disposed inside the cavity and including transparent patterns and light absorption patterns arranged alternately.
